(19) United States
(12) Patent Application Publication
(10) Pub. No.: US 2026/0076112 A1
(43) Pub. Date: Mar. 12, 2026

(54) Selective Directed Assembly-Based Printing of Metal Oxide Dielectric Thin Films

(71) Applicant: Northeastern University, Boston, MA (US)

(72) Inventors: Ahmed Mostafa ABDELAZIZ, Boston, MA (US); Ahmed BUSNAINA, Needham, MA (US)

(21) Appl. No.: 19/109,687

(22) PCT Filed: Sep. 18, 2023
(86) PCT No.: PCT/US2023/033051

§ 371 Date: Mar. 7, 2025

Related U.S. Application Data
(60) Provisional application No. 63/407,600, filed on Sep. 16, 2022.

(51) Int. Cl. H01L 21/02; H01L 21/288

(52) U.S. Cl. CPC H10P 14/6538; H10P 14/46; H10P 14/6342; H10P 14/69391; H10P 14/69392

(57) ABSTRACT

A method for selectively printing metal oxide dielectric films using directed fluidic assembly is provided. The metal oxide films are printed from a liquid suspension of nanoparticulate precursors using a dip coating mechanism. The resulting films can be fully cured at about 100° C. in conjunction with UV photoannealing. The printed metal oxide films can serve as the dielectric material for a variety of passive and active electronic devices. The method reduces cost and energy consumption for the fabrication of electronic devices, and can be used to fabricate devices on flexible polymer substrates.

### CROSS REFERENCE TO RELATED APPLICATIONS

This application claims the priority of U.S. Provisional Application No. 63/407,600 filed 16 Sep. 2022 and entitled “Selective Directed Assembly-Based Printing of Metal Oxide Dielectric Thin Films”, the whole of which is hereby incorporated by reference.

### STATEMENT REGARDING FEDERALLY SPONSORED RESEARCH OR DEVELOPMENT

This invention was made with government support under Grant No. FA8650-20-2-5506 awarded by the Air Force Research Laboratories. The government has certain rights in the invention.

### BACKGROUND

Dielectric (metal oxide) thin films have emerged as a promising candidate material for a wide range of electronic applications such as wearables, disposable circuits, and unconventional displays. This is attributed to their unique properties such as high dielectric constant, wide band gap, and chemical stability. Moreover, their solution-based processing has opened new venues for low cost printable and transparent electronics. However, metal oxide films usually require high annealing temperatures (>400° C.), which limits their application to circuit designs with certain substrates. Also, the lack of selective deposition of the coated films adds complexity to the fabrication process, as it requires further etching of the coated oxide after film deposition.

Printed electronics have been attracting significant interest in a wide range of applications. Active and passive components such as field effect transistors (FETs) and capacitors represent the majority of the basic building blocks of electronic circuits. The capability of printing such devices monolithically on any substrate at lower cost and high throughput paves the way for more cost effective flexible electronic devices, such as active matrix displays, radio frequency (RFID) tags, and sensors.¹⁻⁶ A critical requirement for achieving this target is the capability of printing such electronic components at low-operational voltage, hence the need to print gate dielectrics with high areal capacitance and uniformity.⁷⁻⁹ Traditionally, thin oxide layers have been fabricated using self-assembled monolayers (SAM).^{10, 11} This approach includes surface chemical reactions on the substrate to form an ultrathin oxide layer. However, this process is limited to specific substrates (mainly rigid) that can withstand the chemical reactions and temperatures required for processing these oxide layers. Other approaches for fabricating high-k metal oxide dielectrics include metal anodization and vacuum-based deposition techniques.^{12, 13} Although these techniques have the capability to form high quality metal oxide dielectrics, they still require high temperature annealing (>400° C.) and/or vacuum processing, which makes them incompatible with low-cost processing of printed electronics. Another alternative approach to fabricate high quality metal oxide dielectrics is by using sol-gel chemistry. This solution processing method has been used to fabricate high dielectric oxides from their solution-based precursors at relatively low temperatures.¹⁴⁻¹⁶ However, the reported methods only use spin coating as the coating method for such oxide precursors. For monolithically printed electronics, a more robust approach is needed to facilitate the printing of individual electronic components selectively on different substrates.

### SUMMARY

The present technology provides a method for selectively printing metal oxide dielectric films using directed fluidic assembly. The metal oxide films are printed from a sol-gel suspension of nanoparticulate chemical precursors of a desired metal oxide using a dip coating mechanism. The resulting films can be fully cured at relatively low temperature (for example, about 100° C.) in conjunction with UV photoannealing in a nitrogen atmosphere. The cured film was characterized using x-ray photoelectron spectroscopy (XPS), and the results showed enhancement in the M-O network formation after UV exposure, and the chemical composition ratio of the photoannealed film was in excellent agreement with its metal oxide film counterpart made using atomic layer deposition (ALD). Scanning electron microscopy (SEM) images taken for different printed patterns revealed the capability of the present directed fluidic assembly technique to print oxide films at sub-micron scale with high precision, throughput, and selectivity.

The printed oxide films fabricated using the present technology can be utilized as dielectric layers in both passive and active electronic components. As passive devices, capacitors were made and tested at different frequencies. The results showed high capacitance at high frequencies (up to 1 MHz) with low dissipation factor, which confirms the superior quality of the printed dielectric films. As active components, SWCNT-based FETs were fabricated, and the I-V characteristic curves showed high on/off ratio and mobility, which is in close agreement with values for SWCNT FETs that were made using ALD grown metal oxides as the dielectric layer. Thus, the present technology can be used to selectively print a wide range of metal oxide dielectric materials that can be integrated into microscale and nanoscale passive and active electronic components. The technology also provides a solution for printing high quality oxide films at reduced cost and energy consumption, and is compatible with the utilization of polymer substrates required for wearable and flexible electronics applications.

An aspect of the technology is a method of depositing a patterned metal oxide layer on a substrate. The method includes the following steps: (a) providing (i) a substrate comprising a pattern of voids suitable for use in a directed assembly process and (ii) a colloidal suspension comprising a chemical precursor of a metal oxide in a solvent; (b) treating the suspension to promote polycondensation of the chemical precursor to form metal-oxygen-metal bonds, thereby forming nanoparticles comprising the metal oxide; (c) dip coating the substrate in a suspension comprising the nanoparticles from step (b) and a dip coating solvent, whereby the nanoparticles are assembled in the voids to form a patterned metal oxide layer; (d) treating the patterned metal oxide layer to remove impurities; and (e) densifying the purified metal oxide layer resulting from step (d).

Another aspect of the technology is a metal oxide layer made by a method including the above-described method.

Yet another aspect of the technology is an article containing a metal oxide layer made by the above-described method. The article can be, for example, a microelectronic or nanoelectronic circuit or device, or a component thereof, such as a capacitor, a field effect transistor, or an interconnect.

Still another aspect of the technology is a bottom-up fabrication method for making a microelectronic or nanoelectronic component, wherein the fabrication method includes the above-described method.

The technology can be further summarized in the following list of features.

1. A method of depositing a patterned metal oxide layer on a substrate, the method comprising:
(a) providing (i) a substrate comprising a pattern of voids suitable for use in a directed assembly process and (ii) a colloidal suspension comprising a chemical precursor of a metal oxide in a solvent;
(b) treating the suspension to promote polycondensation of the chemical precursor to form metal-oxygen-metal bonds, thereby forming nanoparticles comprising the metal oxide;
(c) dip coating the substrate in a suspension comprising the nanoparticles from step (b) and a dip coating solvent, whereby the nanoparticles are assembled in the voids to form a patterned metal oxide layer;
(d) treating the patterned metal oxide layer to remove impurities;
(e) densifying the purified metal oxide layer resulting from step (d).

2. The method of feature 1, wherein the treating of step (b) comprises stirring the suspension for a period of time at a temperature above ambient temperature, such as stirring for 12 hours at about 70° C.

3. The method of feature 1 or feature 2, wherein the treating of step (d) comprises heating the patterned metal oxide layer at ambient atmosphere and a temperature above ambient temperature, such as about 75° C.

4. The method of any of the preceding features, wherein the densifying of step (e) comprises subjecting the purified metal oxide layer to UV radiation, such as at a wavelength of about 254 nm, under an inert atmosphere, such as a nitrogen atmosphere.

5. The method of any of the preceding features, wherein the densifying of step (e) comprises heating the purified metal oxide layer at a temperature of at least about 100° C.

6. The method of any of the preceding features, wherein the densifying of step (e) comprises heating the purified metal oxide layer at a temperature in the range from about 100° C. to about 200° C., or from about 100° C. to about 150° C., or from about 100° C. to about 120° C., or from about 90° C. to about 110° C.

7. The method of any of the preceding features, wherein the densifying of step (e) comprises exposing the purified metal oxide layer to UV radiation having a wavelength of about 254 nanometers, at a temperature of about 100° C., in the absence of oxygen, and for a period of about 20-30 minutes.

8. The method of any of the preceding features, wherein the metal oxide layer comprises an oxide comprising one or more metals selected from the group consisting of aluminum, hafnium, silicon, titanium, tin, zinc, and zirconium.

9. The method of feature 8, wherein the metal oxide layer comprises aluminum oxide or hafnium oxide.

10. The method of any of the preceding features, wherein the chemical precursor comprises a salt, such as a nitrate or acetate salt, of the metal selected to form the metal oxide layer.

11. The method of any of the preceding features, wherein the solvent in step (a) is methoxyethanol.

12. The method of any of the preceding features, wherein the dip coating solvent comprises water and or a water-miscible organic solvent, such as an alcohol.

13. The method of any of the preceding features, wherein the patterned substrate provided in (a) comprises a photoresist material that defines said pattern of voids, and wherein the method further comprises, after step (d):
(d1) removing the photoresist material by a lift off process.

14. The method of any of the preceding features, wherein the dip coating of step (c) comprises withdrawal of the substrate from the suspension at a rate of about 100 mm/min.

15. The method of any of the preceding features, wherein the metal oxide layer has a thickness of less than 1 micrometer, or less than 100 nanometers, such as about 25 nanometers.

16. The method of any of the preceding features, wherein the method does not include the use of atomic layer deposition (ALD), chemical vapor deposition (CVD), or spin coating to form said metal oxide layer.

17. The method of any of the preceding features, wherein the substrate comprises silicon, silicon dioxide, or an organic polymer.

18. A metal oxide layer made by a method comprising the method of any of the preceding features.

19. An article comprising the metal oxide layer of feature 18.

20 The article of feature 19, wherein the article is configured as a microelectronic or nanoelectronic circuit or device, or a component thereof.

21. The article of feature 20, wherein the device comprises or consists of a capacitor, a field effect transistor, or an interconnect.

22. A bottom-up fabrication method for making a microelectronic or nanoelectronic component, the fabrication method comprising the method of any of features 1-17.

### BRIEF DESCRIPTION OF DRAWINGS

FIGS. 1A and 1B present a schematic illustration of a selective printing process of an AlOₓ dielectric layer. FIG. 1A shows a printing and soft bake process, and FIG. 1B shows a UV curing process. FIG. 1C is a flow chart of a metal oxide printing process such as that of FIGS. 1A and 1B combined.

FIGS. 2A-2H show results of printed metal oxide characterization. FIG. 2A shows XPS measurements for an “as deposited” film. FIG. 2B shows XPS measurements for a photo annealed film. FIG. 2C shows XPS measurements for a film grown by atomic layer deposition (ALD). FIG. 2D shows chemical composition variation at different curing times. FIGS. 2E-2H show SEM images for different printed patterns after curing.

FIGS. 3A-3B show a schematic representation of a process for fabricating capacitors. FIG. 3A depicts the capacitor structural design, and FIG. 3B shows the fabrication process. FIG. 3C shows optical microscope images of the fabricated capacitor devices. FIG. 3D shows capacitance measurements for 500×500 μm² capacitors at different frequencies.

FIGS. 4A-4C show structural designs of fabricated FETs. FIG. 4A shows a schematic diagram of an FET structure utilizing the printed oxide as a dielectric layer. FIG. 4B shows a schematic diagram of the corresponding fabrication process. FIG. 4C shows an optical micrograph of the fabricated FET transistors with channel length of 20 μm. SWCNTs=single walled carbon nanotubes.

FIG. 5A shows I-V characterization (transfer curve) of an FET as shown in FIGS. 4A-4C. FIG. 5B shows output curves of the same FET. FIGS. 5C and 5D show histograms of field effect mobility (5C) threshold voltage (5D).

FIG. 6A shows transmission electron micrographs of AlOx layers in cross-section, made according to the present technology using different annealing temperatures during UV exposure. FIG. 6B shows the AlOx layer thickness as a function of the annealing temperature.

### DETAILED DESCRIPTION

The present technology provides a novel method for printing metal oxide films from their liquid precursors using directed fluidic assembly. The technique allows selective printing of oxide films at specific locations with high resolution and uniformity. Moreover, by using UV photoannealing combined with heat annealing, the printed patterns can be densified at a relatively low temperature of about 100° C. or less, which allows implementation of the technology on a wide variety of substrates, including substrates containing organic polymers.

The present technology not only eliminates high temperature annealing, but it also eliminates the use of traditional high vacuum techniques for depositing oxide layers, which are well known to be energy and time consuming. By adapting the present technology on an industrial scale, significant cost reduction for electronic component fabrication can be achieved. Moreover, through selective printing of oxide layers, etching steps also can be eliminated, which further simplifies the fabrication process and reduces overall cost.

Testing results showed the superior quality of the printed films as demonstrated by printed capacitors and field effect transistors made using printed dielectric films of the present technology. The capacitors showed an outstanding performance with normalized areal capacitance of 225 nF cm⁻² at 1 MHz, and 0.34×10⁻³ dissipation factor. The SWCNT-based FETs showed performance similar to that of the FETs with an oxide layer deposited by atomic layer deposition (ALD), with ˜10⁵ on/off ratio and 6.89 cm² V⁻¹ s⁻¹ field effect mobility.

The present technology includes several novel features. The method has the capability of printing metal oxide films from liquid precursors using directed fluidic assembly. The resulting films are then cured at a significantly lower temperature (not more than about 100° C.) than used in previous methods of depositing metal oxides. The method achieves precise, highly selective deposition of oxide materials on a large scale, based on use of the directed fluidic assembly technique, which allows printing of a formulated oxide precursor selectively at the desired locations on a chip containing a patterned substrate. This in contrast to traditional spin coating methods, where the oxide layer covers the whole chip surface, requiring etching to remove the unwanted oxide to achieve the desired patterns.

The present technology offers several advantages over previous technologies for making metal oxide films. The technology allows printing of electronic components monolithically using a bottom-up approach, which is very challenging with previous methods due to the difficulty in curing and selectively printing the oxide layers. The technology eliminates the need for high vacuum processing in the fabrication of electronic components, since the whole printing process can be performed at ambient atmosphere and pressure. The technology significantly simplifies the fabrication of electronic components by eliminating vacuum deposition and etching steps during the fabrication process. The technology uses a relatively low curing temperature, making possible the monolithic fabrication of electronic components on flexible, organic polymer substrates with low melting point material. Further, selective printing of the oxide layer in the present technology facilitates printing of electronic components at selective locations on an electronic chip as well as on the backside of an already fabricated chip, which cannot be achieved using traditional methods.

The present technology can be used to print both passive and active electronic components. It prints electrically insulating metal oxides directly on a chip, and can be used to build unique metal oxide structures which, for example, can be coupled with interconnects in electronic circuit fabrication. The printed oxide also can be used in optoelectronic device fabrication as a passivation layer. It further can be used to print various structures in 3D printing. The present technology can replace, or can be used in conjunction with, atomic layer deposition or sputtering of metal oxide films, as well as metal oxide diffusion furnaces.

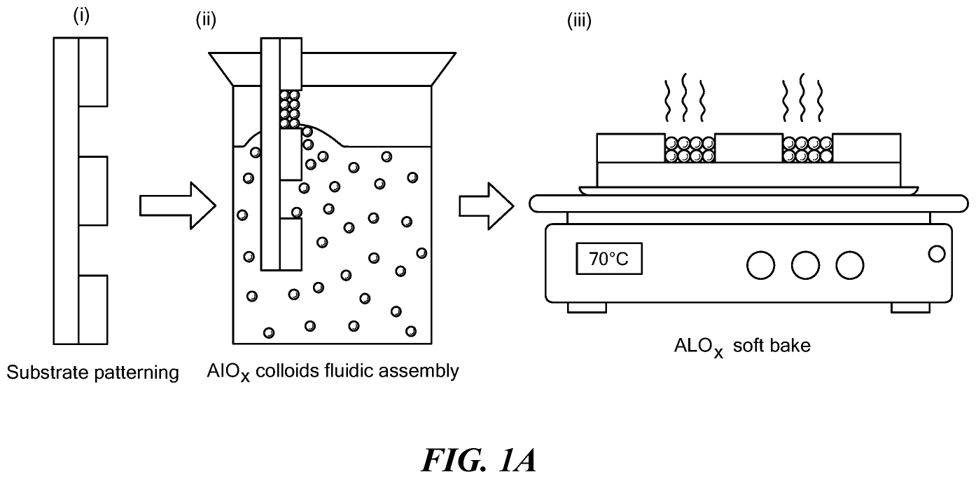

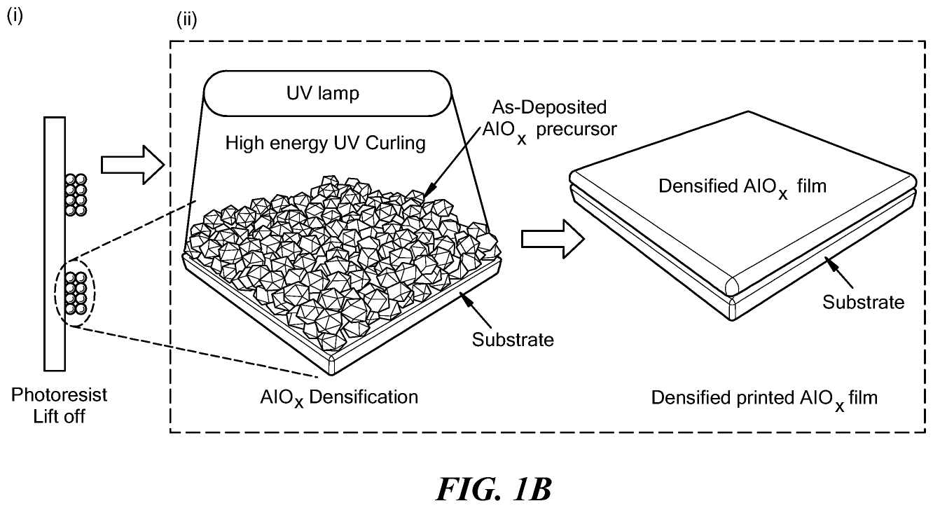

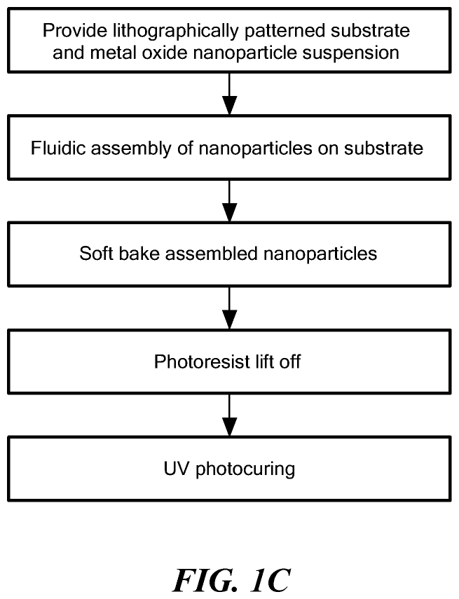

FIG. 1 shows a schematic illustration of a selective printing process of a metal oxide dielectric layer, containing a metal oxide such as AlOx, HfOx, SiOx, TiOx, SnOx, ZnOx, and ZrOx, using a directed fluidic assembly process according to the present technology. After cleaning substrate 101 using O₂ plasma, the substrate is patterned using photolithography with the required patterns for printing the dielectric layer (FIG. 1A(i)). The pattern includes raised sections of photoresist 102 surrounding voids 103. For sub-micron patterning, an E-beam resist (e.g., 950 PMMA, MicroChem Corp.) and E-beam lithography can be utilized. After that, the oxide layer is printed on the substrate from the corresponding precursors utilizing a dip coating device (FIG. 1A(ii)). The patterned substrate was immersed in colloid suspension 104 containing metal oxide nanoparticles which served as the precursor for the metal oxide layer. The patterned substrate was then withdrawn through the surface (air-liquid interface) of the suspension at a speed of, for example, 100 mm/min, which is sufficiently fast that the metal oxide is deposited selectively or entirely within the voids of the patterned substrate. During the substrate withdrawal process, the colloidal particles assemble directly on the designated patterned areas. Subsequently, the substrate is soft baked, for example at 75° C. in ambient atmosphere for about 10 minutes, to remove any solvents remaining inside the printed film (FIG. 1A(iii)) as well as aggregated organic breakdown products. The soft baking process is carried out at a temperature sufficiently high to promote solvent evaporation but below the boiling point of any solvents used. After removal of solvent, the photoresist mask is lifted off (FIG. 1B(i)), leaving patterned layer of deposited, partially purified metal oxide precursor particles 105. The metal oxide precursor layer is then exposed to UV light for curing and densifying the oxide film (FIG. 1B(ii)). Through UV exposure, the printed colloidal sol-gel particles are converted into highly pure and fully densified, continuous metal oxide film 106. It has been shown that UV exposure can anneal sol-gel metal oxide films (Y.-H. Kim, et al., doi:10.1038/nature11434 (2012)).

It should be noted that the current process is different from fluidic assembly using only a functionalized, hydrophobic surface. In that method, the particles avoid the hydrophobic areas of a patterned substrate. With the current fluidic assembly process, a photoresist is used instead to direct the gel particles of a sol-gel suspension into voids or vias. After the dip coating process, the photoresist is stripped away, leaving behind the printed particles only at the vias. During dip coating, some of the particles will be deposited as well on the photoresist surface; however, because of the fast assembly speed of, for example, 100 mm/min, addition to the hydrophobicity of the photoresist compared to the exposed silicon, there will be very little assembly of particles on top of the photoresist surface, and any particles on the photoresist will be stripped away upon photoresist removal.

Three significant chemical reactions take place during the metal oxide film formation process. First, polycondensation of the nanoparticle suspension is carried out before dip coating. This is performed, for example, by stirring the original metal oxide precursor in 2-methoxyethanol for 12 hrs at 70° C. Other organic solvents also can be used. During stirring of the suspension, a chemical change occurs from the original metal nitrate/acetate ligands to 2-methoxyethoxide and hydroxide ligands. Subsequent condensation of these metal alkoxides/hydroxides promote the formation of metal-oxygen-metal (M-O-M) bonds in the solution. Second, impurities are removed after assembly of the nanoparticles on the patterned substrate by soft baking the film, for example at 75° C. in ambient atmosphere. During the soft baking process, solvents, stabilizers, and metal ligands from the film are evaporated or decomposed, and the metal oxide nanoparticles are condensed. Third, film densification occurs where the oxide film is densified through providing enough UV energy to initiate the formation of radical reactions that activate chemical bonding between oxide particles. Before UV exposure, the printed film still has significant aggregation of organic components. The UV irradiation induces photochemical reactions that separate alkoxy groups and further activate the formation of M-O-M network.^{14, 18, 19} With further irradiation, film densification takes place by gradual removal of carbon and excess oxygen residuals from the film. The UV irradiation can be conducted under N₂ atmosphere to prevent ozone formation, and a UV lamp emitting at a wavelength of 253.7 nm (90%) at 25 W can be used at 100° C. for 20-30 minutes, for example. Short emission wavelength is important to supply enough energy for film densification.

### EXAMPLES

### Example 1. Preparation of Ink Precursor Solution

To prepare AlOx precursor, 0.2 M of aluminum nitrate nonahydrate (Sigma Aldrich, USA) was dissolved in 5 ml methoxyethanol, then stirred at 600 rpm for 12 hrs at 70° C. After that, the suspension was filtered using 0.2 μm PTFE filter paper and then used as AlOx precursor. For HfOx precursor, 0.1 M of hafnium isopropoxide isopropanol adduct (Sigma Aldrich, USA) was dissolved in 5 ml methoxyethanol, then stirred at 600 rpm for 24 hrs at 75° C. The suspension was then filtered with 0.2 μm PTFE filter paper and used as HfOx precursor.

### Example 2. Surface Patterning

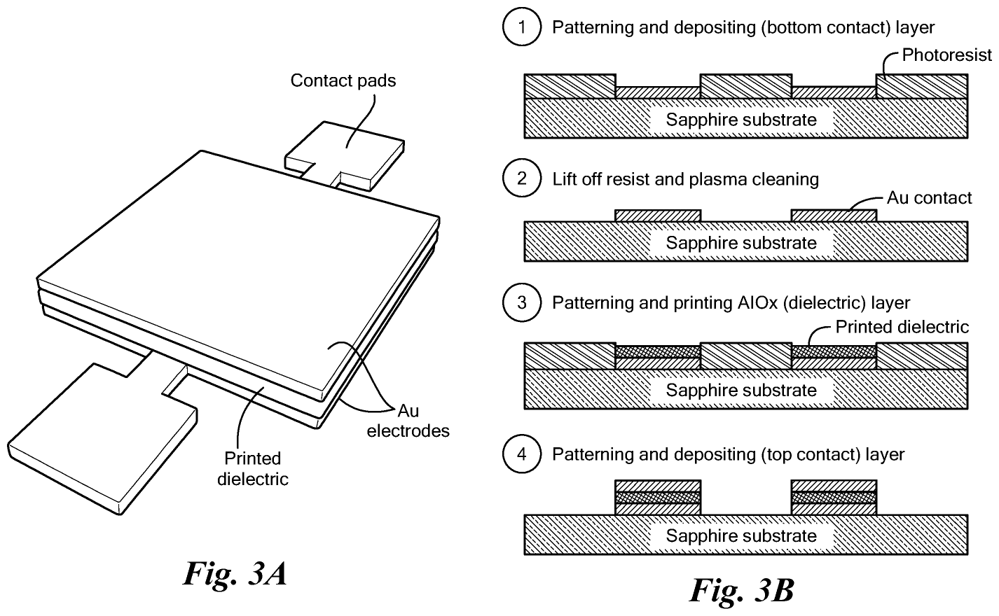

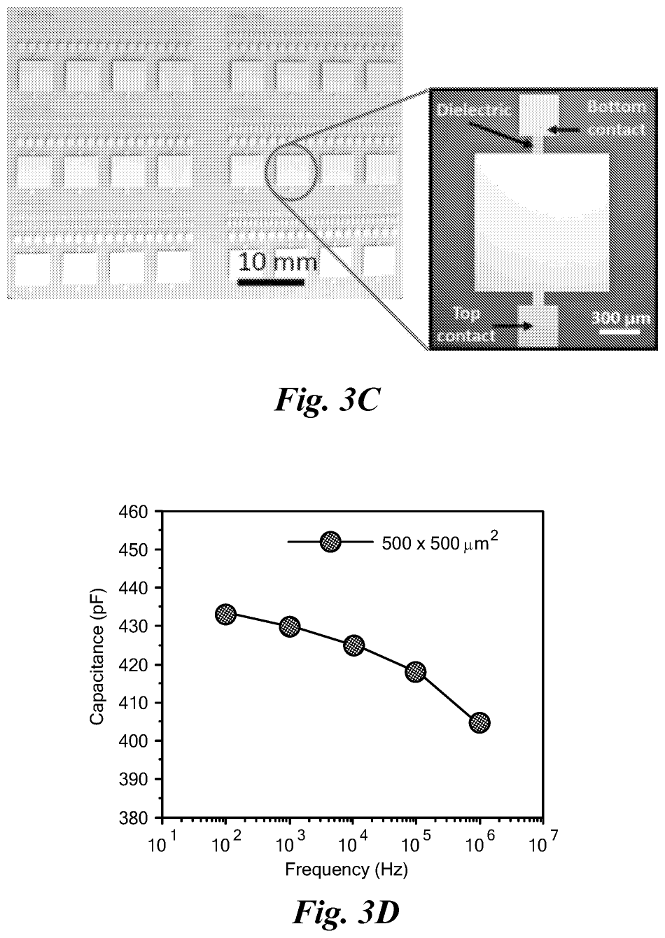

For microscale patterning, a Si substrate was first cleaned with O2 plasma for 2 mins at 150 watts of power. The Si substrate then was spin coated with 5A lift-off resist (LOR, Microposit) at 1000 rpm for 1 min and baked at 160° C. for 5 mins. Subsequently, 1813 positive photoresist (Microposit) was spin coated at 4000 rpm and soft baked at 100° C. The substrate was UV treated using UV mask aligner (Quintel-4000) for 7 secs. The photoresist was then developed using 726 MIF developer for 40 secs and rinsed with H₂O, then dried with N₂ (FIG. 3B, step 1).

For sub-micron scale patterning, the Si substrate was coated with 5A lift-off resist (LOR, Microposit) at 4000 rpm for 1 min and baked at 160° C. for 5 mins. Subsequently, PMMA (950 PMMA, MicroChem Corp.) films with 300 nm were spin coated on a substrate at 5000 rpm for 1 min and subsequently baked in an oven at 100° C. for 30 min. The PMMA film after that was patterned using E-beam lithography, the exposure voltage and current were 30 kV and 40 pA, respectively. The exposure dose was 2 nC/cm. After the E-beam exposure, the film was developed in methyl isobutyl ketone/isopropyl alcohol (MIBK/IPA, 1:3), then rinsed in IPA for 30 s and then in deionized water for 5 min.

### Example 3. Device Fabrication

As passive electronic components, capacitors were fabricated based on the printed oxide layer. See FIGS. 3A-3D. A 20 nm (5 nm Ti/15 nm Au) thickness conductive layer 301 was deposited onto a silver patterned substrate using E-beam deposition. This layer was used as the bottom electrode. Subsequently, the substrate was patterned using lithography to open areas for oxide layer printing. The oxide layer 106 was printed on the substrate from chemical precursors of the desired oxide. The substrate was then annealed at 70° C. for 5 min and then treated under UV for densification inside an N₂ atmosphere as described above. After that, a top Au electrode layer (5 nm Ti /15 nm Au) was deposited on the substrate using E-beam deposition. The bottom and top electrode layers extended to form contact pads 302. To test the fabricated device performance, an LCR precision meter (E4980A Keysight) was used at different frequencies (20 Hz to 2 MHz).

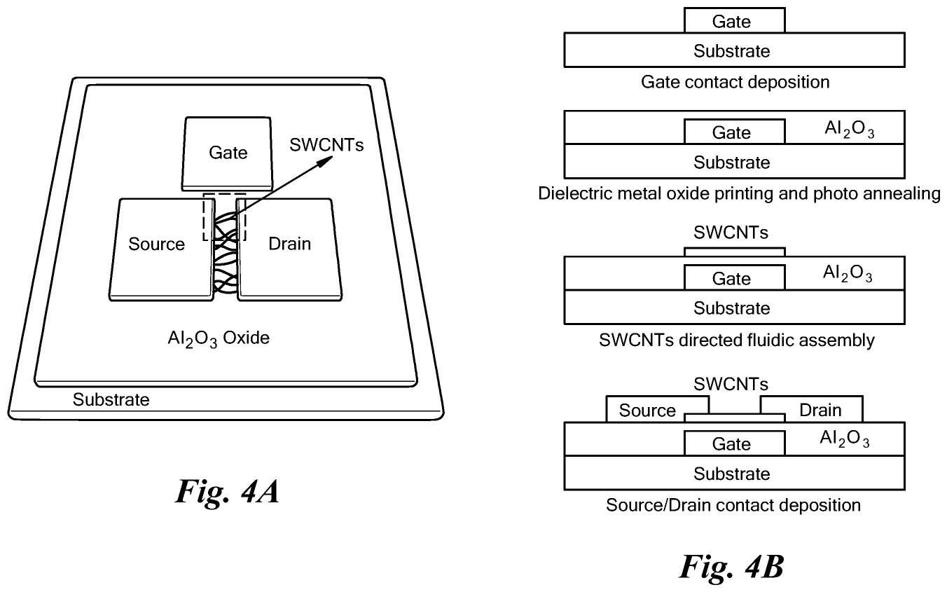

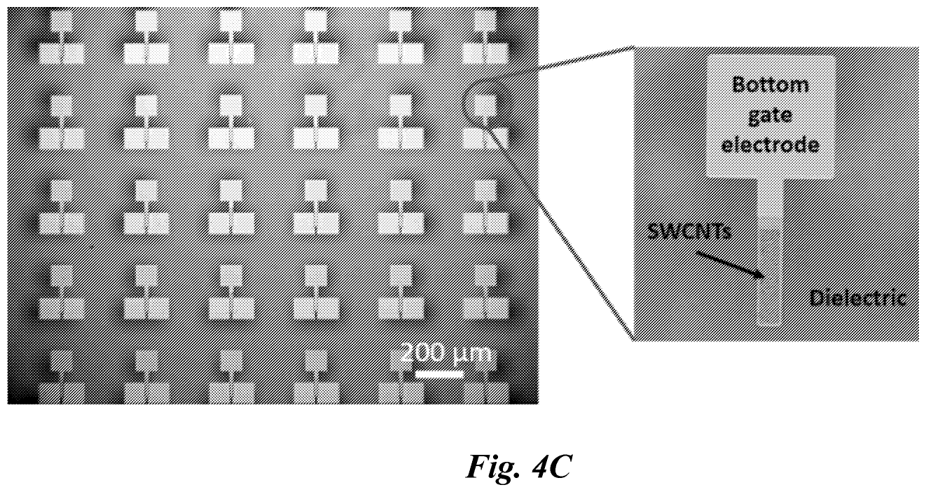

SWCNTs were assembled to serve as FET channels using slow fluidic assembly, as reported previously [17]. See FIGS. 4A-4C. Briefly, source 401, gate 402, and drain 403 structures were formed from Au layers (see FIG. 4B), with Al2O3 layer 106 separating the three contacts. An aqueous suspension of semiconducting SWCNTs (Nanointegres, Inc) at 0.04 mg/ml concentration was used for deposition. A photopatterned substrate 101 with channel width of 20 μm was dipped inside the SWCNT suspension, then withdrawn at 0.05 mm/min withdrawal speed. After dipping, the photoresist was lifted off, then the substrate with the deposited SWCNT channels 404 was annealed at 150° C. to remove moisture and solvents.

### Example 4. Device Characterization

X-ray photoelectron spectroscopy (XPS) was performed using K-alpha (XRA-800 Thermo Fisher Scientific). All measurements were conducted after removing carbon contaminants on the oxide surface. Scanning electron microscopy measurements were conducted using a Supra 25 SEM (Carl Zeiss).

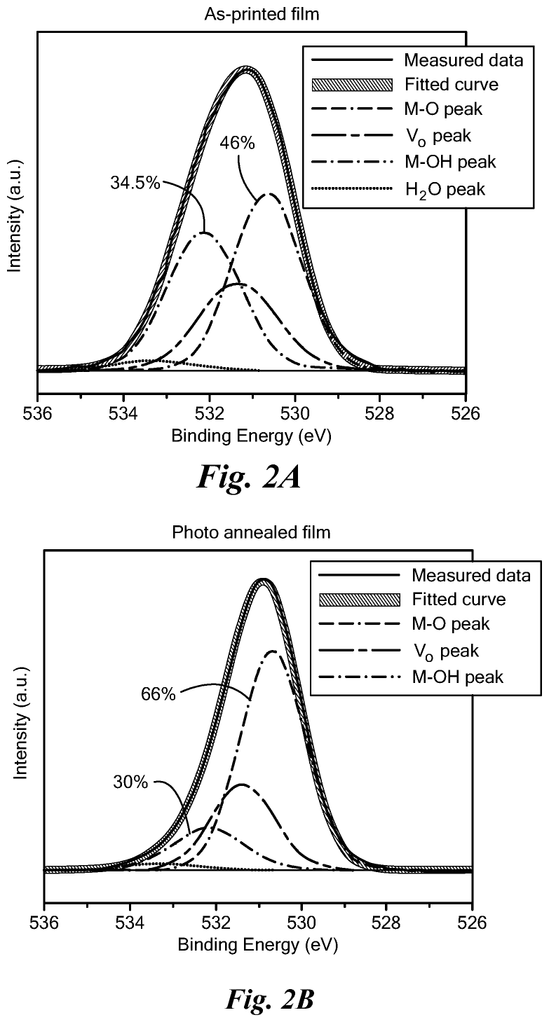

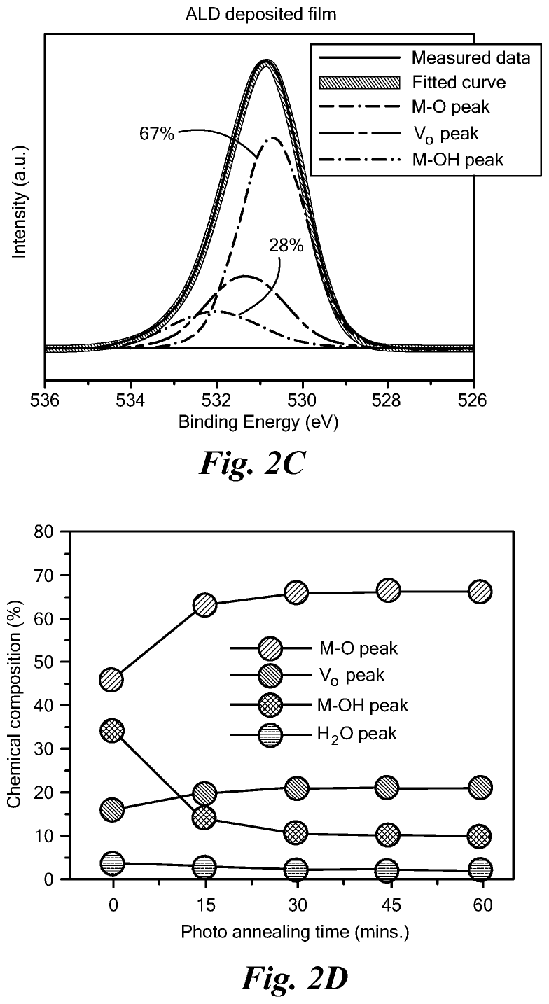

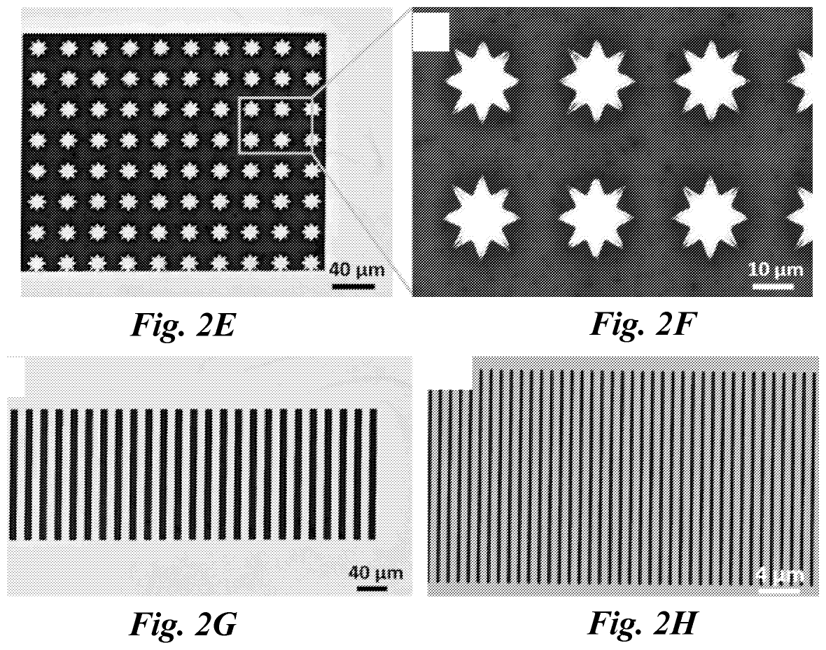

The degree of film densification and its chemical composition were verified via XPS measurements as shown in FIG. 2A. The “as deposited” film O 1S peak was de-convoluted into 4 distinct peaks.^{14, 20, 21} The lowest binding energy peak at 530.84 eV is mainly attributed to oxygen bonded states in AlOₓ stoichiometry. The second peak at 531.43 eV indicates oxygen deficient states in the AlOₓ structure which reflects the presence of unbonded oxygen molecules or oxygen vacancies. The third peak at 532.25 eV is attributed to M-OH binding states, in this case the —OH hydroxyl surface groups attached to aluminum atoms forming aluminum hydroxides. From the first and third peak ratios could be observed that the as-deposited film contains a high percentage of aluminum hydroxides, which is expected for uncured printed suspensions. The fourth peak at 533.31 eV is related to small amounts H₂O species existing in the coated film.²²

FIG. 2B shows XPS O 1S data for the photo annealed film after UV curing for 30 mins. Clearly, the percentage of M-OH species decreased significantly compared to M-O species, which indicates the decomposition of —OH radicals and the formation of M-O network species inside the oxide film. It was observed also that the moisture content inside the film decreased after curing. To compare the quality of the deposited film after UV curing, an O 1S XPS measurement was conducted for an AlOₓ film grown by atomic layer deposition (ALD) as shown in FIG. 2C. The figure shows that there is a strong match between the chemical composition of the deposited AlOₓ film with its ALD counterpart. This indicates complete densification for the UV cured film, and the high quality of the oxide formed was confirmed by this comparison.

FIG. 2D reveals the chemical composition of the film at different points in time during UV curing. The figure shows that with increasing the UV exposure more M-O network species composition is enhanced inside the deposited film the M-O composition is increased from 46% up to 66.1% in 30 mins. On the other hand, the M-OH bonding species composition decreased significantly with UV exposure from 34.5% to 10.6% in 30 mins. The figure shows that oxygen vacancies are increased by UV, which is attributed to chemical decomposition that takes place through the film. The H₂O content slightly decreased as well with exposure. The film was approximately fully densified after 30 mins of UV exposure. This time can be further minimized by increasing the applied heat during UV to higher than 100° C. The cured film thickness measured after 30 mins using ellipsometry was about 25 nm.

FIGS. 2E-2H show SEM images for printed AlOₓ layers with different patterns after UV curing. The images reveal highly uniform printed oxide layer structures. The high resolution of the printed patterns also confirms the outstanding selectivity of the printing process using directed assembly, which facilitates the printing of metal oxide films at sub-micron scale. When E-beam lithography is performed to pattern the substrate, metal oxide-containing features down to at least 100 nm in diameter or extent can be fabricated. Also, the low temperature implemented for curing the oxide (about 100° C.) allows for the use of a wide variety of flexible substrates to print electronic devices, including polymer-based substrates.

To further investigate the quality of the metal oxide structure, the printed dielectric film was used to print micro capacitors and field effect transistors as basic passive and active electronic components demonstrators, respectively. FIG. 3A shows a schematic for the fabricated micro-capacitors on a sapphire substrate. The structure consists of bottom and top Au electrodes with the deposited dielectric layer sandwiched between them. FIG. 3B shows a schematic for the fabrication process. A sapphire substrate was patterned with 20 nm Ti/Au (5 nm Ti, and 15 nm Au) using E-beam as a bottom electrode. After that, the substrate was photo patterned to protect the bottom electrode contact pads before depositing the dielectric layer. The substrate was then plasma cleaned for 10 secs, and dip coated with AlOx precursor suspension at 100 mm/min withdrawal speed. The photoresist was then lifted off to expose the bottom contact pads. Subsequently, the film was photo annealed for 30 mins, using UV exposure inside N₂ atmosphere on a hot plate at 100° C. Finally, the top contact electrode of 20 nm Ti/Au was deposited on the film using E-beam assisted evaporation to complete the fabrication process. FIG. 3C shows optical microscope images of the fabricated capacitors. The layout contains different capacitor dimensions with electrode dimensions as depicted in the inset figure. The capacitor performance was tested using an LCR precision meter to evaluate the capacitance as well as the dissipation factors. The measured capacitance at 0.5 MHz frequency for (20×20), (100×100), (500×500), and (1000×1000) μm² capacitors was 850 fF, 16.3 pF, and 405 pF, and 1.6 nF respectively. The dissipation factor was approximately 0.34×10⁻³, 1.2×10⁻³, 3.7×10⁻³, and 5.5×10⁻³, respectively. The low dissipation factor indicates low leakage currents generated during the measurements which is mainly attributed to the superior quality of the printed oxide dielectric. FIG. 3D shows the capacitance measurements for (500×500) μm² capacitors under different frequencies from 0.1 to 1 MHz. The capacitor showed excellent performance at higher frequencies with normalized areal capacity of 225 nF/cm² at 1 MHz, which reveals their capability to be implemented in high frequency electronic applications.

FIG. 4A shows a schematic of the FET structure utilizing the printed metal oxide as a dielectric layer. The structure consists of a bottom gate contact, a second layer of printed oxide as dielectric layer, a third layer of semiconducting single wall carbon nanotubes (SWCNTs) as semiconductor layer, and source/drain contacts on the top layer. The fabrication procedure is illustrated in FIG. 4B. A sapphire substrate was patterned with 20 nm Ti/Au (5 nm Ti, and 15 nm Au) using E-beam as a bottom gate electrode. Subsequently, the substrate was photo patterned to protect the bottom gate electrode contact pads before depositing the dielectric layer. The substrate was then plasma cleaned for 10 secs, and dip coated with AlOₓ precursor suspension at 100 mm/min withdrawal speed. After photoresist lift-off, a UV curing process similar to that of the capacitor dielectric photo annealing was performed. Subsequently, SWCNTs were deposited as a semiconducting channel on top of the dielectric layer. Finally, source/drain contacts of 20 nm Ti/Au (5 nm Ti, 15 nm Au) were deposited on top to finalize the fabrication process. FIG. 4C shows the fabricated FET transistors with channel length of 20 μm.

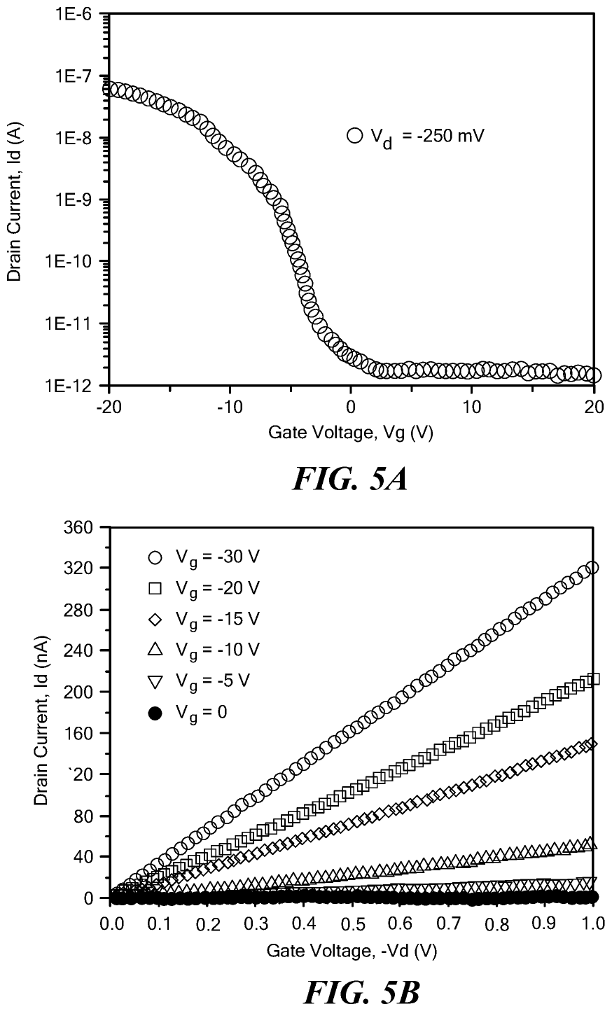

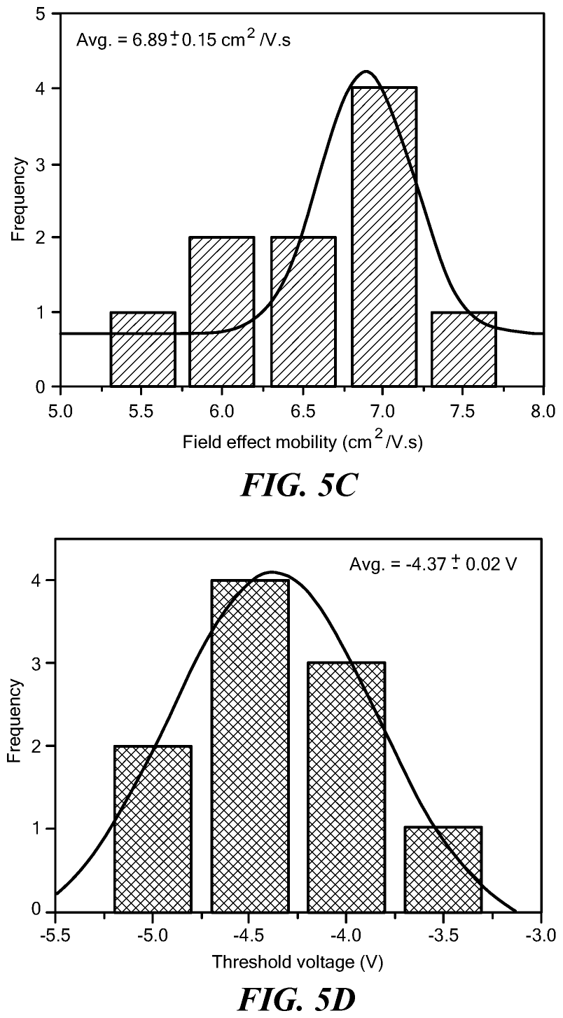

To test the FET device performance, I-V measurements were conducted using a semiconductor parameter analyzer (HP 4156C, Agilent Technologies). FIGS. 5A-5D show the transfer and output characteristic curves of the fabricated FETs. The transfer curve under applied drain voltage of −0.2V reveals a current on/off ratio of about 8.5×10⁴, which agrees with values reported in the literature using similar semiconducting SWCNT FETs.^{23, 24} The mobility histogram fitting of 10 different devices shows that the FETs exhibited field-effect mobility of 6.89 cm² V⁻¹ s⁻¹ (FIG. 5C). The devices also showed threshold voltage of about −4.37 V averaged over 10 measured devices (FIG. 5D). The I-V characteristics reveal good performance for the fabricated FETs compared to its SWCNT FET counterparts reported in literature,²⁵ which are mainly based on ALD deposited dielectric layers. This further confirms the superior quality of the printed dielectric metal oxide used in the device fabrication.

### Example 5. Effect of Annealing Temperature

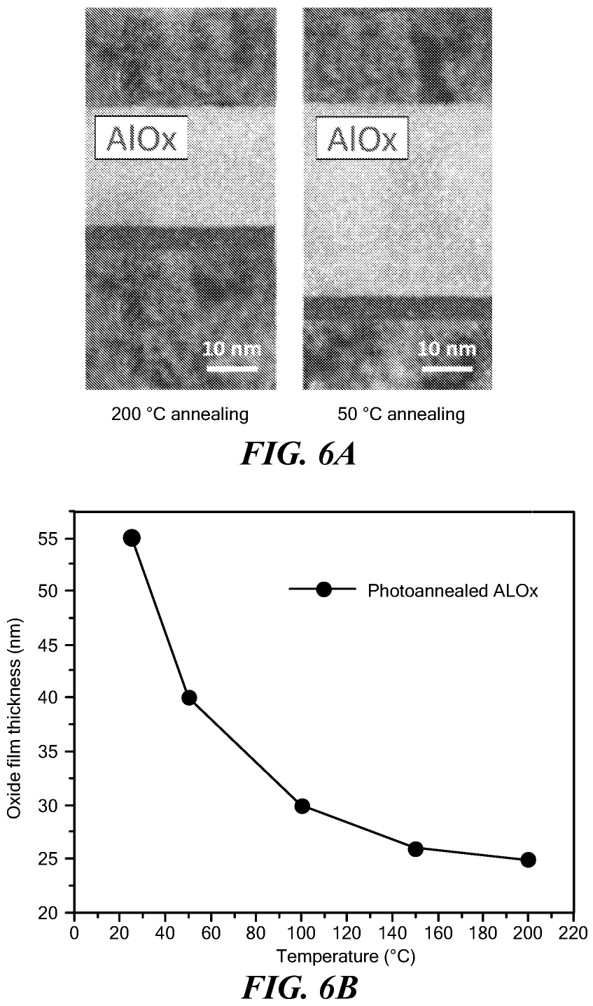

The effect of annealing temperature in the presence of UV and nitrogen atmosphere was investigated. AlOx layers were prepared as described in Example 2, except that the annealing temperature during UV exposure was varied. The thickness of the AlOx layer, and therefore its degree of densification and purity, was a function of the annealing temperature. FIG. 6A shows that the AlOx layer thickness was considerably reduced upon annealing at 200° C. compared to annealing at 50° C. The curve in FIG. 6B reveals that annealing temperatures of about 100° C. or higher produced more fully densified layers, while temperatures below about 100° C. yielded less densification.

The following US patents are hereby incorporated by reference in their entireties. Directed assembly of a conducting polymer, U.S. Pat. No. 8,703,501; Highly organized single-walled carbon nanotube networks and method of making using template guided fluidic assembly, U.S. Pat. No. 8,784,673.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### References

1. Forrest, S. R., The path to ubiquitous and low-cost organic electronic appliances on plastic. nature 2004, 428 (6986), 911-918.
2. Roberts, M. E.; Mannsfeld, S. C.; Queralto, N.; Reese, C.; Locklin, J.; Knoll, W.; Bao, Z., Water-stable organic transistors and their application in chemical and biological sensors. Proceedings of the National Academy of Sciences 2008, 105 (34), 12134-12139.
3. Kelley, T. W.; Baude, P. F.; Gerlach, C.; Ender, D. E.; Muyres, D.; Haase, M. A.; Vogel, D. E.; Theiss, S. D., Recent progress in organic electronics: Materials, devices, and processes. Chemistry of Materials 2004, 16 (23), 4413-4422.
4. Dimitrakopoulos, C. D.; Malenfant, P. R., Organic thin film transistors for large area electronics. Advanced materials 2002, 14 (2), 99-117.
5. Someya, T.; Sekitani, T.; Iba, S.; Kato, Y.; Kawaguchi, H.; Sakurai, T., A large-area, flexible pressure sensor matrix with organic field-effect transistors for artificial skin applications. Proceedings of the National Academy of Sciences 2004, 101 (27), 9966-9970.
6. Facchetti, A.; Marks, T. J., Transparent electronics. From Synthesis to Applications 2010.
7. Facchetti, A.; Yoon, M. H.; Marks, T. J., Gate dielectrics for organic field-effect transistors: new opportunities for organic electronics. Advanced Materials 2005, 17 (14), 1705-1725.
8. Nomura, K.; Ohta, H.; Takagi, A.; Kamiya, T.; Hirano, M.; Hosono, H., Room-temperature fabrication of transparent flexible thin-film transistors using amorphous oxide semiconductors. nature 2004, 432 (7016), 488-492.
9. Kamiya, T.; Nomura, K.; Hosono, H., Present status of amorphous In—Ga—Zn—O thin-film transistors. Science and Technology of Advanced Materials 2010.
10. Yoon, M.-H.; Facchetti, A.; Marks, T. J., σ-π molecular dielectric multilayers for low-voltage organic thin-film transistors. Proceedings of the National Academy of Sciences 2005, 102 (13), 4678-4682.
11. Klauk, H.; Zschieschang, U.; Pflaum, J.; Halik, M., Ultralow-power organic complementary circuits. nature 2007, 445 (7129), 745-748.
12. Choi, Y.; Kim, I.-D.; Tuller, H. L.; Akinwande, A. I., Low-voltage organic transistors and depletion-load inverters with high-K pyrochlore BZN gate dielectric on polymer substrate. IEEE transactions on electron devices 2005, 52 (12), 2819-2824.
13. Zhang, X.-H.; Domercq, B.; Wang, X.; Yoo, S.; Kondo, T.; Wang, Z. L.; Kippelen, B., High-performance pentacene field-effect transistors using Al2O3 gate dielectrics prepared by atomic layer deposition (ALD). Organic Electronics 2007, 8 (6), 718-726.
14. Jo, J. W.; Kim, J.; Kim, K. T.; Kang, J. G.; Kim, M. G.; Kim, K. H.; Ko, H.; Kim, Y. H.; Park, S. K., Highly stable and imperceptible electronics utilizing photoactivated heterogeneous sol-gel metal-oxide dielectrics and semiconductors. Advanced Materials 2015, 27 (7), 1182-1188.
15. Socrates, G., Infrared and Raman characteristic group frequencies: tables and charts. John Wiley & Sons: 2004.
16. Kim, Y.-H.; Heo, J.-S.; Kim, T.-H.; Park, S.; Yoon, M.-H.; Kim, J.; Oh, M. S.; Yi, G.-R.; Noh, Y.-Y.; Park, S. K., Flexible metal-oxide devices made by room-temperature photochemical activation of sol-gel films. Nature 2012, 489 (7414), 128-132.
17. Kim, Y. L., Engineering highly organized and aligned single walled carbon nanotube networks for electronic device applications: interconnects, chemical sensor, and optoelectronics. 2013.
18. Lin, Y.; Faber, H.; Zhao, K.; Wang, Q.; Amassian, A., M. 70 McLachlan, TD Anthopoulos. Adv. Mater 2013, 25, 4340.
19. Imai, H.; Hirashima, H.; Awazu, K., Alternative modification methods for sol-gel coatings of silica, titania and silica-titania using ultraviolet irradiation and water vapor. Thin solid films 1999, 351 (1-2), 91-94.
20. Liu, A.; Liu, G.; Zhu, H.; Shin, B.; Fortunato, E.; Martins, R.; Shan, F., Eco-friendly water-induced aluminum oxide dielectrics and their application in a hybrid metal oxide/polymer TFT. RSC advances 2015, 5 (105), 86606-86613.
21. Haija, M. A.; Guimond, S.; Uhl, A.; Kuhlenbeck, H.; Freund, H.-J., Adsorption of water on thin V2O3 (0 0 0 1) films. Surface science 2006, 600 (5), 1040-1047.
22. Meier, M.; Hulva, J.; Jakub, Z.; Pavelec, J.; Setvin, M.; Bliem, R.; Schmid, M.; Diebold, U.; Franchini, C.; Parkinson, G. S., Water agglomerates on Fe3O4 (001). Proceedings of the National Academy of Sciences 2018, 115 (25), E5642-E5650.
23. Kim, K.-T.; Lee, K. W.; Moon, S.; Park, J. B.; Park, C.-Y.; Nam, S.-J.; Kim, J.; Lee, M.-J.; Heo, J. S.; Park, S. K., Conformally Gated Surface Conducting Behaviors of Single-Walled Carbon Nanotube Thin-Film-Transistors. Materials 2021, 14 (12), 3361.
24. Wang, W.-H.; Abbasi, S. A.; Chai, Z.; Jeong, H.; Busnaina, A., Solution processed all-carbon transistors via directed assembly and transfer printing of CNT channel and electrodes. Applied Physics Letters 2020, 117 (13), 133101.
25. Jang, S.; Kim, B.; Geier, M. L.; Prabhumirashi, P. L.; Hersam, M. C.; Dodabalapur, A., Fluoropolymer coatings for improved carbon nanotube transistor device and circuit performance. Applied Physics Letters 2014, 105 (12), 122107.

1. A method of depositing a patterned metal oxide layer on a substrate, the method comprising:
(a) providing (i) a substrate comprising a pattern of voids suitable for use in a directed assembly process and (ii) a colloidal suspension comprising a chemical precursor of a metal oxide in a solvent;
(b) treating the suspension to promote polycondensation of the chemical precursor to form metal-oxygen-metal bonds, thereby forming nanoparticles comprising the metal oxide;
(c) dip coating the substrate in a suspension comprising the nanoparticles from step (b) and a dip coating solvent, whereby the nanoparticles are assembled in the voids to form a patterned metal oxide layer;
(d) treating the patterned metal oxide layer to remove impurities;
(e) densifying the purified metal oxide layer resulting from step (d).

2. The method of claim 1, wherein the treating of step (b) comprises stirring the suspension for a period of time at a temperature above ambient temperature, such as stirring for 12 hours at about 70° C.

3. The method of claim 1, wherein the treating of step (d) comprises heating the patterned metal oxide layer at ambient atmosphere and a temperature above ambient temperature, such as about 75° C.

4. The method of claim 1, wherein the densifying of step (e) comprises subjecting the purified metal oxide layer to UV radiation, such as at a wavelength of about 254 nm, under an inert atmosphere, such as a nitrogen atmosphere.

5. The method of claim 1, wherein the densifying of step (e) comprises heating the purified metal oxide layer at a temperature of at least about 100° C.

6. The method of claim 1, wherein the densifying of step (e) comprises heating the purified metal oxide layer at a temperature in the range from about 100° C. to about 200° C., or from about 100° C. to about 150° C., or from about 100° C. to about 120° C., or from about 90° C. to about 110° C.

7. The method of claim 1, wherein the densifying of step (e) comprises exposing the purified metal oxide layer to UV radiation having a wavelength of about 254 nanometers, at a temperature of about 100° C., in the absence of oxygen, and for a period of about 20-30 minutes.

8. The method of claim 1, wherein the metal oxide layer comprises an oxide comprising one or more metals selected from the group consisting of aluminum, hafnium, silicon, titanium, tin, zinc, and zirconium.

9. The method of claim 8, wherein the metal oxide layer comprises aluminum oxide or hafnium oxide.

10. The method of claim 1, wherein the chemical precursor comprises a salt, such as a nitrate or acetate salt, of the metal selected to form the metal oxide layer.

11. The method of claim 1, wherein the solvent in step (a) is methoxyethanol.

12. The method of claim 1, wherein the dip coating solvent comprises water and or a water-miscible organic solvent, such as an alcohol.

13. The method of claim 1, wherein the patterned substrate provided in (a) comprises a photoresist material that defines said pattern of voids, and wherein the method further comprises, after step (d):
(d1) removing the photoresist material by a lift off process.

14. The method of claim 1, wherein the dip coating of step (c) comprises withdrawal of the substrate from the suspension at a rate of about 100 mm/min.

15. The method of claim 1, wherein the metal oxide layer has a thickness of less than 1 micrometer, or less than 100 nanometers, such as about 25 nanometers.

16. The method of claim 1, wherein the method does not include the use of atomic layer deposition (ALD), chemical vapor deposition (CVD), or spin coating to form said metal oxide layer.

17. The method of claim 1, wherein the substrate comprises silicon, silicon dioxide, or an organic polymer.

18. A metal oxide layer made by a method comprising the method of claim 1.

19. An article comprising the metal oxide layer of claim 18.

20. The article of claim 19, wherein the article is configured as a microelectronic or nanoelectronic circuit or device, or a component thereof.

21. The article of claim 20, wherein the device comprises or consists of a capacitor, a field effect transistor, or an interconnect.

22. A bottom-up fabrication method for making a microelectronic or nanoelectronic component, the fabrication method comprising the method of claim 1.
